(19) United States
(12) Patent Application Publication
(10) Pub. No.: US 2012/0298195 A1
(43) Pub. Date: Nov. 29, 2012

(54) MOISTURE-RESISTANT FILM, MADE OF FLUORINATED POLYMER AND INORGANIC OXIDE, FOR PHOTOVOLTAIC USE

(75) Inventors: Dominique Plee, Lima (PE); Dominique Jousset, Serquigny (FR); Francois Beaume, Saint Genis Laval (FR); Anthony Bonnet, Saint Laurent de Mure (FR)

(73) Assignee: ARKEMA FRANCE, Colombes (FR)

(21) Appl. No.: 13/522,054

(22) PCT Filed: Jan. 7, 2011
(86) PCT No.: PCT/FR11/50026

§ 371 Date: Aug. 7, 2012

(30) Foreign Application Priority Data
Jan. 14, 2010 (FR) 1050227

(51) Int. Cl. H01L 31/02; B32B 27/08; B32B 27/20

(52) U.S. Cl. 136/256; 428/328; 428/216; 428/220

(57) ABSTRACT

The invention relates to a multilayer structure that includes: a layer of a composition including a fluorinated polymer and a zinc oxide (ZnO), said ZnO being present in said composition in the form of particles having a weight proportion of less than 1%, said ZnO particles having a size between 10 to 100 nm, and an adhesion promoter present in the body and/or surface of said layer; and at least one oxide layer (MOx) selected from among silicon oxide and aluminum oxide, and having a thickness of from 20 to 200 nm. Aid structure has excellent properties of transparency within the visible range, excellent properties of opacity to UV rays, as well as good mechanical resistance and aging resistance while having excellent moisture barrier properties. Said structure can thus be advantageously used in the front surface of photovoltaic panels or fro protecting organic light-emitting diodes.

### FIELD OF THE INVENTION

The present invention relates to a multilayer structure comprising a layer of a composition comprising a fluorinated polymer, zinc oxide of nanometric size and an adhesion promoter, and also at least one layer of silicon oxide or aluminum oxide, which has very good adhesion properties. Due to their transparency in the visible range and their opacity with respect to UV radiation and also their excellent water-barrier and oxygen-barrier properties, these structures are especially intended for use as frontsheets in a photovoltaic cell or as protective layers for organic light-emitting diodes.

### PRIOR ART

A photovoltaic cell consists of a semiconductor material sandwiched between two metal electrodes, the whole being protected by a frontsheet and a backsheet. The frontsheet of a photovoltaic cell must mainly protect the elements of the cell against any mechanical attack. It must also prevent effects caused by aging induced especially by UV radiation, water and oxygen. In order to use sunlight as efficiently as possible, the frontsheet of a photovoltaic cell must, of course, have high transmittance in a certain spectral range, which, for example, extends from 400 to 1100 nm for a cell based on crystalline silicon.

It is known practice to manufacture photovoltaic cells with a frontsheet made of glass, an inexpensive and widely available material, which also has high mechanical strength. However, a glass frontsheet has several drawbacks: a ceiling transmittance of 92% in the range from 400 to 1100 nm, a large weight and low impact strength, requiring particular precautions during the transportation, installation and use of the photovoltaic cells.

Plastic frontsheets overcome several of these drawbacks. Specifically, plastics exist that have a transmittance higher than that of glass, which are lighter and which have satisfactory impact strength.

Thus, it is known practice to use fluorinated polymers in general and especially PVDF (polyvinylidene difluoride VDF fluoride) to manufacture films for protecting objects and materials, on account of their very good resistance to bad weather, to UV radiation and to visible light, and to chemical products. These films have very good heat resistance for external applications subject to severe climatic conditions (rain, cold, heat) or transformation processes performed at high temperature (>130° C.).

Monolayer films based on fluorinated polymers (copolymer of ethylene and of tetrafluoroethylene or ETFE; PVDF; copolymer of ethylene and of propylene or FEP, etc.), sold by companies such as DuPont, Asahi Glass, Saint-Gobain and Rowland Technologies, are already used as frontsheets for photovoltaic cells.

However, these films may have insufficient water-barrier properties. One solution for improving these water-barrier properties is described in application US 2001/0 009 160. Said document describes a frontsheet for photovoltaic cells comprising a UV-resistant fluorinated polymer film and a moisture-resistant film which comprises a transparent film on which is layered an inorganic oxide. It is described that no UV absorber is necessary in order for the fluorinated polymer to have UV-resistance properties. However, the structure cannot be entirely satisfactory for the frontsheet of photovoltaic cells intended for long periods of exposure to light radiation, since its UV strength remains insufficient.

Generally, to protect a polymer film against degradation by UV rays, organic UV absorbers and/or mineral fillers are incorporated therein. For the backsheet, it is known that the addition of inorganic fillers such as TiO₂, SiO₂, CaO, MgO, CaCO₃, Al₂O₃ and others in a fluorinated polymer, such as a vinylidene fluoride polymer or copolymer, may lead to a quite drastic degradation with production of HF (hydrogen fluoride) when the mixing is performed in the melt at high temperature to disperse the filler. One route for using these fillers with, for example, PVDF consists in introducing these inorganic fillers using an acrylic masterbatch. To this end, the inorganic fillers are dispersed in a methyl methacrylate polymer or copolymer (PMMA), and this masterbatch is then mixed with the molten PVDF. The presence of a PMMA gives rise to drawbacks such as inferior UV stability in comparison with a pure PVDF. Such a film comprising a layer of a fluorinated polymer/acrylic polymer/mineral filler tripartite composition is described, for example, in document WO 2009/101 343.

Organic UV absorbers are inert materials that absorb and diffuse UV radiation. However, their use is limited on account of their drawbacks, namely limited spectral coverage, their degradation on aging and their migration accompanied by exudation. One solution, which consists in limiting the content of UV absorber, was proposed, for example, by the Applicant in document EP 1 382 640, which describes films that are transparent to visible light and opaque to UV radiation, said films consisting of two layers, one of which comprises PVDF, PMMA, an acrylic elastomer and a UV absorber. The results presented in Examples 1 to 5 show that no exudation is observed when a film 15 μm thick is kept for 7 days in an oven. The limitation of the content of UV absorber in said document cannot, however, be suitable for the manufacture of films intended for longer periods of use, as is the case for photovoltaic cells.

It would therefore be desirable to have a moisture-resistant structure comprising a layer of a composition that allows the manufacture of a film which has good transparency properties in the visible region, opacity to UV radiation and good adhesion between different layers, mechanical strength and age resistance.

### SUMMARY OF THE INVENTION

The Applicant's studies have made it possible to develop precisely such a structure,

One subject of the invention is a multilayer structure comprising:
a layer of a composition comprising a fluorinated polymer and zinc oxide (ZnO), said ZnO being present in said composition in the form of particles in a mass proportion of less than 1%, said particles having a size ranging from 10 to 100 nm, and also an adhesion promoter present in the mass and/or at the surface of said layer;
at least one layer of oxide (MOx) chosen from silicon oxide and aluminum oxide, with a thickness of from 20 to 200 nm and preferentially from 70 to 110 nm.

The combination of these particular layers gives the structure excellent properties in terms of resistance to UV, to visible light, to chemical products, mechanical strength and scratch resistance, and also oxygen-barrier and water-barrier properties. According to a particularly advantageous effect of the invention, the structure as defined withstands delamination on aging very well. Moreover, the structure has excellent transparency in the visible region. Another advantage of these nanofillers is that their action is different from that of organic UV absorbers: they are not consumed, do not migrate and are not exuded from the composition, which allows for long-term maintenance of the performance. These properties taken together allow its advantageous use as a frontsheet for a photovoltaic panel or as a protective layer for organic light-emitting diodes.

The particular nanometric size allows good dispersion of the particles within the polymer mass, without reducing the transparency of the composition, and allows excellent UV stability, even in low proportions.

Advantageously, the mass proportion of ZnO is from 0.1% to 0.95% and preferably from 0.6% to 0.9%. For contents significantly higher than 1%, the Applicant in fact observed that the transmittance in the visible region is significantly decreased. The size of the ZnO particles may be from 25 to 40 nm and preferably from 30 to 35 nm.

The ZnO particles may advantageously be covered with a surface treatment, for example coated with silane. This increases the compatibility with the fluorinated polymer and leads to the production of a homogeneous suspension that is stable over time while at the same time limiting the degradation of the fluorinated polymer composition during its use.

In addition, the composition of fluorinated polymer and of ZnO that is useful for the invention may be free of acrylic polymers, which eliminates the risk of producing unpleasant odors during transformation. To generate adhesion, promoters are added such as a polar-functionalized fluorinated polymer and optionally a silane. It is understood that the functionalized fluorinated polymer is added into the mass of the layer, i.e. by mixing, or is present as a coating of low thickness on the face intended to come in contact with the oxide layer (MOx).

Preferentially, the fluorinated polymer is a vinylidene difluoride homopolymer or a copolymer of vinylidene difluoride and of at least one other fluorinated monomer.

The layer of the composition advantageously has a thickness of between 10 and 100 μm, advantageously between 15 and 90 μm and preferentially between 20 and 80 μm.

According to a first embodiment of the invention, at least one layer of MOx is deposited directly onto the layer of the composition of fluorinated polymer.

According to a second embodiment of the invention, at least one layer of MOx is deposited onto a layer of a support polymer (polymer-MOx) different than the composition of fluorinated polymer, of adhesion promoter and of ZnO, said support polymer possibly being a fluorinated polymer or a polyester such as polyethylene terephthalate.

According to this second embodiment, the structure may comprise a stack of n layers of (polymer-MOx) with n ranging from 2 to 10.

It is pointed out that these two methods are combinable, i.e. a layer of MOx may be deposited onto the composition of fluorinated polymer, of adhesion promoter and of ZnO and onto another layer of polymer.

The structure according to the invention may also comprise a layer of transparent, rigid polymer such as polymethyl methacrylate or polycarbonate.

The structure according to the invention may comprise a layer containing a polymer chosen from polyolefins.

According to one possibility offered by the invention, the adhesion promoter is a polar functionalized polymer, for example a Kynar ADX®, present in the layer in a proportion ranging from 1% to 50% of the mass of said layer. Kynar ADX® is a modified fluorinated polymer obtained by irradiation-grafting of a graftable compound onto a fluorinated polymer. Examples of such a component may be found especially in document FR 2 876 626.

Advantageously, the layer of composition comprising a fluorinated polymer, a zinc oxide and an adhesion promoter also comprises a silane, for example a glycidyl epoxy silane, present in the layer in a proportion ranging from 0.01% to 0.5% of the mass of said layer.

According to the invention, the multilayer structure may take the form of a film, i.e. its total thickness is from 10 to 1500 μm.

Another aspect of the invention is a photovoltaic panel in which the frontsheet consists of the structure or film according to the invention. The invention also relates to the use of the structure or film according to the invention for the manufacture of the frontsheet in a photovoltaic panel or for protecting organic light-emitting diodes.

### DESCRIPTION OF THE FIGURES

The invention and the advantages it affords will be understood more clearly in the light of the detailed description that follows and of the attached FIG. 1, in which:

FIG. 1a is a view in cross section of a first variant of the structure according to the invention;

FIG. 1b is a view in cross section of a second variant of the structure according to the invention;

FIG. 1c is a view in cross section of a third variant of the structure according to the invention;

FIG. 1d is a view in cross section of a fourth variant of the structure according to the invention.

### DETAILED DESCRIPTION OF THE INVENTION

The research conducted by the Applicant, directed toward improving the known films based on fluorinated polymers, which are transparent in the visible region and opaque to UV radiation, has led it to the development of a multilayer structure comprising a layer of a composition comprising a fluorinated polymer and zinc oxide of nanometric size comprising an adhesion promoter on the inorganic oxides and also at least one layer of silicon oxide or of aluminum oxide.

The fluorinated polymer included in the composition according to the invention is prepared by polymerization of one or more monomers of formula (I):

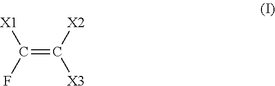

in which:
X₁ denotes H or F;
X₂ and X₃ denote H, F, Cl, a fluoroalkyl group of formula CₙFₘHₚ— or a fluoroalkoxy group CₙFₘHₚO—, n being an integer between 1 and 10, m an integer between 1 and (2n+1), p being equal to 2n+1−m.

Examples of monomers that may be mentioned include hexafluoropropylene (HFP), tetrafluoroethylene (TFE), vinylidene fluoride (VDF, CH₂═CF₂), chlorotrifluoroethylene (CTFE), perfluoroalkyl vinyl ethers such as CF₃—O—CF═CF₂, CF₃—CF₂—O—CF═CF₂ or CF₃—CF₂CF₂—O—CF═CF₂, 1-hydropentafluoropropene, 2-hydropentafluoropropene, dichlorodifluoroethylene, trifluoroethylene (VF₃), 1,1-dichlorofluoroethylene and mixtures thereof, diolefins containing fluorine, for example diolefins such as perfluorodiallyl ether and perfluoro-1,3-butadiene.

Examples of fluorinated polymers that may be mentioned include:
TFE homopolymers or copolymers, especially PTFE (polytetrafluoroethylene), ETFE (ethylene-tetrafluoroethylene copolymer) and also TFE/PMVE (tetrafluoroethylene-perfluoro(methyl vinyl) ether copolymer), TFE/PEVE (tetrafluoroethylene-perfluoro(ethyl vinyl) ether copolymer), TFE/PPVE (tetrafluoroethylene-perfluoro(propyl vinyl) ether copolymer), E/TFE/HFP (ethylene-tetrafluoroethylene-hexafluoropropylene terpolymers) copolymers;
VDF homopolymers or copolymers, especially PVDF and VDF-HFP copolymers;
CTFE homopolymers or copolymers, especially PCTFE (polychlorotrifluoroethylene) and E-CTFE (ethylene-chlorotrifluoroethylene copolymer).

Preferably, the fluorinated polymer is a VDF homopolymer or copolymer.

Advantageously, the fluorinated comonomer that is copolymerizable with VDF is chosen, for example, from vinyl fluoride; trifluoroethylene (VF₃); chlorotrifluoroethylene (CTFE); 1,2-difluoroethylene; tetrafluoroethylene (TFE); hexafluoropropylene (HFP); perfluoro(alkyl vinyl) ethers such as perfluoro(methyl vinyl) ether (PMVE), perfluoro(ethyl vinyl) ether (PEVE) and perfluoro(propyl vinyl) ether (PPVE); perfluoro(1,3-dioxole); perfluoro(2,2-dimethyl-1,3-dioxole) (PDD), and mixtures thereof.

Preferably, the fluorinated comonomer is chosen from chlorotrifluoroethylene (CTFE), hexafluoropropylene (HFP), trifluoroethylene (VF₃) and tetrafluoroethylene (TFE), and mixtures thereof. The comonomer is advantageously HFP, since it copolymerizes well with VDF and affords good thermomechanical properties. Preferably, the copolymer comprises only VDF and HFP.

Preferably, the fluorinated monomer is a VDF homopolymer (PVDF) or a VDF copolymer such as VDF-HFP containing at least 50% by mass of VDF, advantageously at least 75% by mass of VDF and preferably at least 90% by mass of VDF. Examples that may be mentioned more particularly include VDF homopolymers or copolymers containing more than 75% of VDF and the remainder of HFP, below: Kynar® 710, Kynar® 720, Kynar® 740, Kynar Flex® 2850, Kynar Flex® 3120, sold by the company Arkema.

Advantageously, the VDF homopolymer or copolymer has a viscosity ranging from 100 Pa·s to 3000 Pa·s, the viscosity being measured at 230° C., at a shear rate of 100 s⁻¹ using a capillary rheometer. Specifically, this type of polymer is well suited to extrusion. Preferably, the polymer has a viscosity ranging from 500 Pa·s to 2900 P·s, the viscosity being measured at 230° C., at a shear rate of 100 s⁻¹ using a capillary rheometer.

The zinc oxide included in the composition according to the invention serves as opacifier in the UV region (185 to 400 nm), and acts as a sunscreen, such that a film prepared from the composition according to the invention is an opaque film, mainly by scattering/reflection of the UV rays.

The size of the filler particles is within the range from 10 to 100 nm, for example 25 to 40 nm and preferably from 30 to 35 nm. The mass content of mineral filler in the composition is less than 1% by mass, for example from 0.1% to 0.95% and preferably from 0.6 to 0.9%. This content and the small particle size ensure good transparency properties in the visible region (400 to 700 nm) for a film manufactured from the composition according to the invention.

The particle size may be measured, for example, by photon correlation spectroscopy according to standard ISO 13321:1996. Advantageously, in the composition according to the invention, the ZnO particles have a surface treatment, this treatment possibly making said particles hydrophobic. This has the effect of preventing the degradation of the fluorinated polymers, especially of PVDF, during the compounding and transformation steps. They may be coated with a hydrophobic coating.

According to one embodiment, the ZnO particles are coated with silane or with silane-based compounds. An example of this type consists of the ZnO powder sold under the name Zano®20 Plus by the company Umicore.

The fluorinated polymer composition may be prepared via a process comprising a step of incorporating in the melt said nanometric filler directly into the fluorinated polymer. This preparation method ensures good dispersion of the nanometric ZnO particles to give the structure that is manufactured from said composition good UV opacity, while at the same time conserving good transparency in the visible region. During the operation in the molten route, between 1% and 50% of Kynar ADX® (fluoropolymer resin) by mass relative to the layer to be formed and optionally up to 0.5% of silane (by mass relative to the mass of the layer), an example of which is glycidyl epoxy silane, are incorporated.

The layer of the fluorinated polymer composition included in the structure according to the invention may be in film form.

This film is opaque to UV radiation and transparent in the visible region, while at the same time maintaining very good dimensional stability properties at the temperatures used for the manufacture of a frontsheet or of a backsheet and thereafter of a photovoltaic panel. Moreover, the film of the layer of the fluorinated polymer composition has long-term stability.

The film of the layer of the fluorinated polymer composition is manufactured, according to a first embodiment, by blown-film extrusion at a temperature ranging from 240 to 260° C. This technique consists in coextruding, generally from bottom to top, a thermoplastic polymer through a circular die. The extrudate is simultaneously longitudinally drawn by a drawing device, usually rolls, and blown with a constant volume of air trapped between the die, the drawing system and the wall of the film. The blown film is cooled, generally by an air blowing ring at the die outlet.

Whether it is by extrusion or by blown film, the fluorinated layer containing the ZnO particles may be a monolayer or a bilayer. In the latter case, one of the layers contains the adhesion promoter(s).

Advantageously, the small size of the inorganic filler particles present in the composition used for the manufacture of the film, and also the nature of these fillers, make it possible to obtain the film by the extrusion-blow molding technique at temperatures of 240-260° C. without entailing any degradation of the fluorinated polymer present in said composition. This makes it possible to keep the particular properties of this polymer intact, namely its very good resistance to bad weather, to UV radiation and to oxygen.

According to another embodiment, this film is manufactured according to the steps below:
mixing on a calendar of the nanometric ZnO into the molten fluorinated polymer with the adhesion promoter, at a temperature ranging from 220 to 260° C., preferably at 240° C.;
hot-pressing (at a temperature of 220 to 230° C.) of this mixture to obtain first a thicker film (for example 150 μm thick) and then pressing this again into thinner films of variable thickness, for example ranging from 20 to 80 μ.

The structure according to the invention also comprises a layer of MOx. M is chosen from aluminum and silicon. Advantageously, x is between 1 and 2, for example between 1.3 and 1.7.

This deposit may be produced by physical vapor deposition (PVD) or by chemical vapor deposition (CVD). The deposit may also be a chemical-physical hybrid.

A physical vapor deposition that may be mentioned is cathode sputtering. It is generally performed under vacuum, for example at a pressure of a few tenths of a torr or of a few tons.

Chemical vapor deposition may be performed at atmospheric pressure, under vacuum or under high vacuum, plasma-assisted, to be compatible with the thermal stabilities of polymers. The reagent for forming the MOₓ layer may be in liquid form or in aerosol form. The chemical deposition may be assisted by laser, ultraviolet radiation or by plasma, such as the microwave plasma CVD or plasma enhanced CVD (PECVD) techniques. Preferentially, the deposit is produced by PECVD.

For PVD, precursors based on SiO₂ and/or Si may be used.

For CVD, reagents such as SiH₄ or hexamethyldisiloxane are used (particularly for PECVD).

These deposition techniques are known to those skilled in the art, who may refer, for example, to the following reference publication “Reactive Sputtering Deposition” by Depla, D. and Mahieu, S., 2008, Springer or the “Handbook of Plasma Processing Technology” by Rossnagel, S. M., Cuomo, J. J. and Westwood, 1990, William Andrew Publishing/Noyes.

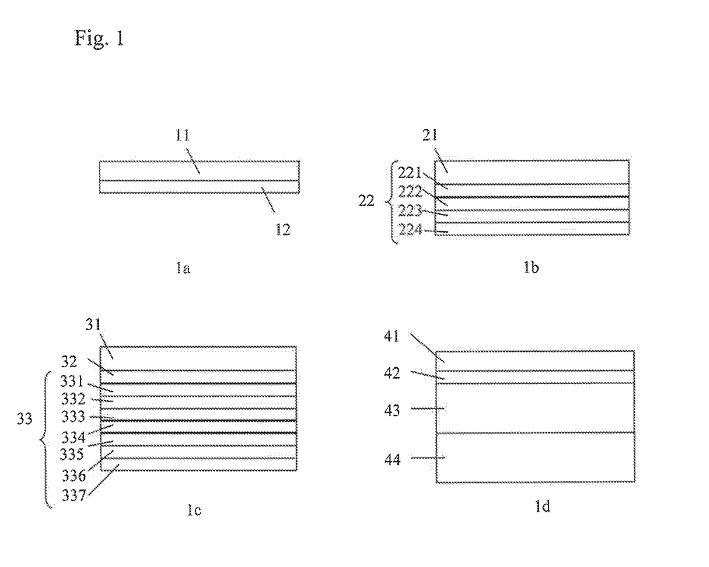

As shown in FIG. 1a, the layer of MOx oxide 12 may be deposited directly onto the layer of the fluorinated polymer composition 11 according to a first variant of the invention.

According to a second variant of the invention, the layer of MOx oxide may be deposited onto a layer of another polymer. The various layers may be combined by means of adhesives, for example of acrylic or urethane type.

For example, FIG. 1b describes a variant of the structure of the invention in which the layer of the fluorinated polymer composition 21 is laminated using an adhesive (not shown) to a multilayer film 22 consisting of a first polymer film 221 onto which is deposited the layer of MOx 222, an adhesive 223 for adhering a second polymer film 224.

In the case where the deposition is performed on a layer of another polymer different than the fluorinated polymer composition, the deposition may be performed on another layer of a transparent polymer to form a polymer-MOx, for example one of the fluorinated polymers already listed or a polyester such as a polyethylene terephthalate. In the case where it is a fluorinated polymer, it is preferentially ETFE or PVDF.

Preferentially, the polymer is a polyester. Preferentially, the layer of the transparent polymer ranges from 5 to 20 μm.

This assembly may be produced by lamination.

Advantageously, the structure comprises a stack of n layers of polymer-MOx, n ranging from 2 to 10. For example, the structure of FIG. 1c describes a variant of the structure of the invention where n is equal to 2 in which a layer of MOx oxide 32 is deposited directly onto the layer of the fluorinated polymer composition 31 and is laminated using an adhesive (not shown) to a multilayer film 33 consisting of a first polymer film 331 onto which is deposited a layer of MOx 332, an adhesive 333 for adhering a second polymer film 334 onto which is also deposited another layer of MOx 335, an adhesive 336 making it possible to adhere a third polymer film 337.

For example, PET-SiOx films are sold by the company Alcan.

The structure may also comprise a layer of rigid, transparent polymer such as polycarbonate or polymethyl methacrylate in order to improve the mechanical strength of the structure. With this layer of rigid, transparent polymer, the structure may be used to manufacture rigid panels. Preferentially, the thickness of the layer of rigid polymer ranges from 500 to 4000 μm.

The structure may also comprise a layer of polymer capable of encapsulating photovoltaic cells or organic light-emitting diodes. This polymer may be, for example, a polyolefin such as copolymers of ethylene and of vinyl acetate or the polyolefin grafted with a polyamide described in patent application FR 2 930 556, namely a layer comprising a polyamide-grafted polymer, this polyamide-grafted polymer comprising a polyolefin trunk containing a residue of at least one unsaturated monomer (X) and at least one polyamide graft in which:
the polyamide graft is attached to the polyolefin trunk via the residue of the unsaturated monomer (X) comprising a function capable of reacting via a condensation reaction with a polyamide bearing at least one amine end and/or at least one carboxylic acid end,
the residue of the unsaturated monomer (X) is attached to the trunk by grafting or copolymerization,
   said polyamide-grafted polymer comprising:
from 50% to 95% by mass of the trunk of polyolefin comprising the unsaturated monomer (X),
from 5% to 50% by mass of polyamide grafts,
   and the flow temperature of this polyamide-grafted polymer being greater than or equal to 75° C., this flow temperature being defined as the highest temperature among the melting points T_{f} and the glass transition temperatures T_{g} of the polyamide graft and of the polyolefin trunk, said layer containing less than 20% by mass of tackifying resin relative to the total mass of the layer. Advantageously, the layer comprising the polyamide-grafted polymer is adjacent to said oxide layer (MOx), such that the latter layer is between the layer of a composition comprising a fluorinated polymer, a zinc oxide (ZnO) and the adhesion promoter, and the layer comprising the polyamide-grafted polymer.

It may also comprise coupling agents and/or organic peroxides.

The thickness of this polymer layer preferentially ranges from 20 to 700 μm, for example from 50 to 500 μm. An advantage of this structure is that it may be laminated directly on photovoltaic cells or light-emitting diodes. This is particularly advantageous for manufacturers of light-emitting diodes or photovoltaic panels: specifically, it is conventionally necessary to add a first layer of encapsulant and then a protective layer. With this particular structure, the manufacturing processes can be simplified. An advantage of this structure is that it can be laminated directly onto photovoltaic cells or light-emitting diodes.

For example, the structure in FIG. 1d describes a structure variant in which the layer of MOx oxide 42 is deposited directly onto a film of the fluorinated polymer composition 41, this film being laminated using an adhesive (not shown) onto one face of a layer of rigid, transparent polymer 43 and a layer of encapsulating polymer 44 being applied to the other face of the rigid polymer.

The structure according to the invention may take the form of a film, i.e. it may have a total thickness ranging from 10 to 1500 μm.

The structure or the film according to the invention may be used as a frontsheet protection for photovoltaic panels. Preferentially, the composition of fluorinated polymer, of adhesion promoter and of ZnO of the structure is in contact with the external environment. The photovoltaic cells of the panel may be manufactured using sensors of any type, for instance “standard” sensors based on monocrystalline or polycrystalline doped silicon; thin-layer sensors formed, for example, from amorphous silicon, cadmium telluride, copper-indium disilenide or organic materials may also be used.

The panel may also comprise layers of encapsulating polymer and a protective backsheet.

To assemble the various layers and to form the panel, any type of pressing technique may be used, for instance hot pressing, vacuum pressing or lamination, in particular hot lamination. The manufacturing conditions will be readily determined by a person skilled in the art.

The structure may also be used for protecting organic light-emitting diodes.

Other characteristics and advantages of the invention will emerge on reading the implementation examples that follow.

### SERIES-1: Manufacture of Films

A masterbatch containing 7.5% “surface-treated nanometric ZnO” (Zano20Plus) in Kynar 1000HD was prepared on a co-rotating twin-screw extruder (diameter 27 mm, L/D=44) under the following conditions: introduction of the filler in the molten zone, nominal temperature of 230° C., screw speed of 250 rpm, flow rate of 20 kg/h. A smooth white rod is obtained, which is then granulated. The granules may have a shrinkage bubble at the center, but are free of fine degradation bubbles. This masterbatch is then incorporated into Kynar 1000HD or Kynarflex 3120-50 by dry-mixing granules, to give, respectively, the mixtures S2-A (in Kynar 1000HD) and S2-B to S2-F (in Kynarflex 3120-50). The degree of incorporation of the masterbatch defines the content of nanometric ZnO in the final mixture as indicated in the table below.

A mixture of Kynar ADX® and of 0.25% of glycidyl epoxy silane is prepared under similar conditions in the same equipment. Kynar ADX® is a polyvinylidene difluoride fluoride (PVDF) comprising polar functions of maleic anhydride type (5000 ppm).

These granule mixtures are then extruded on a single-screw film extruder as a blown film (screw diameter 30 mm, L/D=25, die diameter 50 mm, gap 1.2 mm) under the following conditions: temperature 250° C., drawing speed 5.4 m/min, BUR 2.55.

A film of transparent appearance is obtained.

Deposition of SiOx onto the film obtained is then performed by PECVD using hexamethyldisiloxane on the adhesion promoter side. This film treated with SiOx has improved barrier properties relative to the film without deposit.

### SERIES-2: Measurement of the UV Absorbance and of the Transparency in the Visible Region

The films obtained have a thickness close to 50 μm and are analyzed in terms of absorbance and transmittance. The absorbance and the transmittance of these films are measured on a Varian Cary 300 spectrophotometer equipped with an integration sphere (with an angle of 8°). The film holder is installed at the sphere entry and the Spectralon is placed on the reflectance sample holder. The base line is recorded with the film holder empty. The UV spectra of the films are obtained under the following parameters:
spectral module
range: 200-800 nm
speed: 12 nm/min
lamp change: 350 nm
mode: transmittance
SBW: 2.0 nm

It was chosen to compare the absorbance values at 340 nm (wavelength corresponding to an absorbance minimum in the UV region for the mixtures with nanometric ZnO). The measured absorbance value was extrapolated to a theoretical film thickness of 50 μm by a rule of 3 on the thickness, in order to facilitate the comparisons and since the absorbance varies linearly with the thickness.

The transmittance comparison is performed at 450 nm for all the mixtures.

The results are collated in Table 1 below.

TABLE 1

| | | | | Abs | % T |
|---|---|---|---|---|---|
| | | Kynar | Presence of | (340 nm)- | (450 nm)- |
| Examples | % ZnO | matrix | SiOx | SERIES2 | SERIES2 |
| S2-A | 1 | 1000HD | no | 1.34 | 72.2 |
| S2-B | 1 | 3120-50 | no | 1.46 | 77.4 |
| S2-C | 0.9 | 3120-50 | no | 1.1 | 84 |
| S2-D | 0.8 | 3120-50 | no | 1.01 | 85 |
| S2-E | 0.7 | 3120-50 | no | 0.88 | 84 |
| S2-F | 0.6 | 3120-50 | no | 0.72 | 87.5 |
| S2-G | 0.6 | 3120-50 | yes | 0.77 | 85.5 |

1. A multilayer structure comprising:
a layer of a composition comprising a fluorinated polymer and zinc oxide (ZnO), said ZnO being present in said composition in the form of particles in a mass proportion of less than 1%, said ZnO particles having a size ranging from 10 to 100 nm, and also an adhesion promoter present in the mass and/or at the surface of said layer;
at least one layer of oxide (MOx) having a thickness of from 20 to 200 nm selected from the group consisting of silicon oxide and aluminum oxide.

2. The structure as claimed in claim 1, in which the mass proportion of ZnO is from 0.1% to 0.95%.

3. The structure as claimed in claim 1, in which the size of the ZnO particles is from 25 to 40 nm.

4. The structure as claimed in claim 1, in which the ZnO particles have a surface treatment.

5. The structure as claimed in claim 1, in which the composition is free of acrylic polymers.

6. The structure as claimed in claim 1, in which the fluorinated polymer is a vinylidene difluoride homopolymer, or a copolymer of vinylidene difluoride and of at least one other fluorinated monomer.

7. The structure as claimed in claim 1, containing PVDF and ZnO, the ZnO particles having a size ranging from 30 to 35 nm and the mass content of the ZnO filler being from 0.5% to 6%.

8. The structure as claimed in claim 1, in which the layer of the composition has a thickness of between 10 and 100 μm.

9. The structure as claimed in claim 1, in which the layer of MOx has a thickness ranging from 70 to 110 nm.

10. The structure as claimed in claim 1, in which at least one layer of MOx is deposited directly onto the layer of the fluorinated polymer composition.

11. The structure as claimed in claim 1, comprising a layer of MOx deposited onto a layer of a support polymer (polymer-MOx) different than the composition of fluorinated polymer and of ZnO, said support polymer being a fluorinated polymer or a polyester.

12. The structure as claimed in claim 1, characterized in that it comprises a stack of n layers of (polymer-MOx) with n ranging from 2 to 10.

13. The structure as claimed in claim 1, further comprising a layer of transparent, rigid.

14. The structure as claimed in claim 1, further comprising a layer containing a polymer chosen from polyolefins.

15. The structure as claimed in claim 1, characterized in that the adhesion promoter is a polar functionalized polymer present in the layer in a proportion ranging from 1% to 50% of the mass of said layer.

16. The structure as claimed in claim 1, characterized in that said composition comprising a fluorinated polymer, a zinc oxide and an adhesion promoter further comprising a silane present in the layer in a proportion ranging from 0.01% to 0.5% of the mass of said layer.

17. The structure as claimed in claim 1, characterized in that it also comprises a layer comprising a polyamide-grafted polymer, this polyamide-grafted polymer comprising a polyolefin trunk containing a residue of at least one unsaturated monomer (X) and at least one polyamide graft, in which:
the polyamide graft is attached to the polyolefin trunk via the residue of the unsaturated monomer (X) comprising a function that is capable of reacting via a condensation reaction with a polyamide bearing at least one amine end and/or at least one carboxylic acid end,
the residue of the unsaturated monomer (X) is attached to the trunk by grafting or copolymerization,
said polyamide-grafted polymer comprising:
from 50% to 95% by mass of the trunk of polyolefin comprising the unsaturated monomer (X),
from 5% to 50% by mass of polyamide grafts,
and the flow temperature of this polyamide-grafted polymer being greater than or equal to 75° C., this flow temperature being defined as the highest temperature among the melting points T_{f} and the glass transition temperatures T_{g} of the polyamide graft and of the polyolefin trunk, said layer containing less than 20% by mass of tackifying resin relative to the total mass of the layer.

18. The structure as claimed in claim 15, characterized in that the layer comprising the polyamide-grafted polymer is adjacent to said oxide layer (MOx), such that the latter layer is between said layer of a composition comprising a fluorinated polymer, a zinc oxide (ZnO) and an adhesion promoter, and the layer comprising the polyamide-grafted polymer.

19. A film comprising the structure as claimed in claim 1 and in which the total film thickness is from 10 to 1500 μm.

20. A photovoltaic panel in which the frontsheet consists of the structure as claimed in claim 1.

21. (canceled)
